(19) United States
(12) Patent Application Publication
(10) Pub. No.: US 2026/0342361 A1
(43) Pub. Date: Oct. 29, 2026

(54) LOW DENSITY PARITY CHECK TECHNIQUES IN WIRELESS COMMUNICATIONS

(71) Applicant: QUALCOMM Incorporated, San Diego, CA (US)

(72) Inventors: Pinar SEN, San Diego, CA (US); Wei YANG, San Diego, CA (US); Hobin KIM, San Diego, CA (US); Jing JIANG, San Diego, CA (US)

(21) Appl. No.: 19/660,021

(22) Filed: Apr. 27, 2026

Related U.S. Application Data
(60) Provisional application No. 63/796,933, filed on Apr. 29, 2025.

(51) Int. Cl. H03M 13/11; H04L 1/00

(52) U.S. Cl. CPC H03M 13/116; H03M 13/1174; H04L 1/0013

(57) ABSTRACT

Low density parity check (LDPC) coding techniques may involve puncturing a parity check column and not puncturing a systematic LDPC column (e.g., transmitting the full systematic LDPC code). For example, the base graph matrix may not include punctured systematic nodes. The parity check column that is punctured may be a double edged node (e.g., have at least one entry with two edges or degrees). The remainder of the parity check columns may form a triangular matrix, which may simplify encoding. The transmitting device may map coded bits to a modulation constellation such that systematic bits, and bits of a check node connected to the punctured column, are transmitted in higher-reliability portions of the modulation constellation.

### CROSS REFERENCE

This Patent Application claims the benefit of U.S. Provisional Patent Application No. 63/796,933 by SEN et al., entitled “LOW DENSITY PARITY CHECK TECHNIQUES IN WIRELESS COMMUNICATIONS,” filed Apr. 29, 2025, assigned to the assignee hereof, and expressly incorporated by reference herein.

### TECHNICAL FIELD

This disclosure relates generally to wireless communication, and more specifically to systems, devices, methods, and techniques associated with low density parity check (LDPC) techniques in wireless communications.

### DESCRIPTION OF THE RELATED TECHNOLOGY

Communication systems are deployed to provide communication services such as voice, video, packet data, messaging, or broadcast, among others. A communication system may include a wireless communication network (such as a radio access network (RAN)) that supports communication between wireless communication devices such as network entities (such as base stations), client devices (such as one or more user equipments (UEs)), and others. Such devices may communicate with one another using a variety of protocols (such as radio access technologies (RATs)), including those of cellular-based systems such as fourth generation (4G) systems (such as Long Term Evolution (LTE) systems), fifth generation (5G) systems (such as 5G New Radio (5G-NR) systems), and sixth generation (6G) systems. A wireless communication network may support communication by implementing system resources (such as frequency resources, time resources, spatial resources) in accordance with a wireless communication protocol.

### SUMMARY

The systems, methods, and devices of this disclosure each have several innovative aspects, no single one of which is solely responsible for the desirable attributes disclosed herein. The following is a summary of some non-limiting aspects of the disclosure:

A method for wireless communications by a wireless device is described. The method may include obtaining a set of information bits to be transmitted from the wireless device, generating a parity check matrix based on the set of information bits, the parity check matrix associated with a base graph matrix, where the base graph matrix includes a set of systematic columns used to generate a set of systematic bits corresponding to the set of information bits via application of the parity check matrix to the set of information bits, where the base graph matrix includes a set of parity check columns used to generate a set of parity bits from the set of information bits via application of the parity check matrix to the set of information bits, the parity check matrix generated by applying a circulant identity matrix to each entry of the base graph matrix, where at least a first column of the set of parity check columns is a punctured column and a remainder of the set of parity check columns form a triangular matrix, and transmitting a codeword including the set of systematic bits and a portion of the set of parity bits generated using non-punctured parity check columns of the set of parity check columns.

A wireless device for wireless communications is described. The wireless device may include a processing system that includes processor circuitry and memory circuitry that stores code. The processing system may be configured to cause the wireless device to obtain a set of information bits to be transmitted from the wireless device, generate a parity check matrix based on the set of information bits, the parity check matrix associated with a base graph matrix, where the base graph matrix includes a set of systematic columns used to generate a set of systematic bits corresponding to the set of information bits via application of the parity check matrix to the set of information bits, where the base graph matrix includes a set of parity check columns used to generate a set of parity bits from the set of information bits via application of the parity check matrix to the set of information bits, the parity check matrix generated by applying a circulant identity matrix to each entry of the base graph matrix, where at least a first column of the set of parity check columns is a punctured column and a remainder of the set of parity check columns form a triangular matrix, and transmit a codeword including the set of systematic bits and a portion of the set of parity bits generated using non-punctured parity check columns of the set of parity check columns.

Another wireless device for wireless communications is described. The wireless device may include means for obtaining a set of information bits to be transmitted from the wireless device, means for generating a parity check matrix based on the set of information bits, the parity check matrix associated with a base graph matrix, where the base graph matrix includes a set of systematic columns used to generate a set of systematic bits corresponding to the set of information bits via application of the parity check matrix to the set of information bits, where the base graph matrix includes a set of parity check columns used to generate a set of parity bits from the set of information bits via application of the parity check matrix to the set of information bits, the parity check matrix generated by applying a circulant identity matrix to each entry of the base graph matrix, where at least a first column of the set of parity check columns is a punctured column and a remainder of the set of parity check columns form a triangular matrix, and means for transmitting a codeword including the set of systematic bits and a portion of the set of parity bits generated using non-punctured parity check columns of the set of parity check columns.

A non-transitory computer-readable medium storing code for wireless communications is described. The code may include instructions executable by one or more processors to obtain a set of information bits to be transmitted from the wireless device, generate a parity check matrix based on the set of information bits, the parity check matrix associated with a base graph matrix, where the base graph matrix includes a set of systematic columns used to generate a set of systematic bits corresponding to the set of information bits via application of the parity check matrix to the set of information bits, where the base graph matrix includes a set of parity check columns used to generate a set of parity bits from the set of information bits via application of the parity check matrix to the set of information bits, the parity check matrix generated by applying a circulant identity matrix to each entry of the base graph matrix, where at least a first column of the set of parity check columns is a punctured column and a remainder of the set of parity check columns form a triangular matrix, and transmit a codeword including the set of systematic bits and a portion of the set of parity bits generated using non-punctured parity check columns of the set of parity check columns.

In some examples of the method, wireless devices, and non-transitory computer-readable medium described herein, the first column includes at least one value greater than one.

In some examples of the method, wireless devices, and non-transitory computer-readable medium described herein, the circulant identity matrix may be a Z by Z identity matrix that may be shifted in accordance with a cyclic shift value of a corresponding element of the base graph matrix, and where available cyclic shift values for Z may be selected based on a quantity of edges of the base graph matrix, where an edge of the base graph matrix corresponds to an element of the base graph matrix that may have an adjacent non-zero element of the base graph matrix.

In some examples of the method, wireless devices, and non-transitory computer-readable medium described herein, respective values of respective elements of the base graph matrix corresponds to a quantity of cyclic shift values to apply to the respective elements.

Some examples of the method, wireless devices, and non-transitory computer-readable medium described herein may further include performing one or more row permutations or column permutations on an original base graph matrix to generate the base graph matrix that forms the triangular matrix.

In some examples of the method, wireless devices, and non-transitory computer-readable medium described herein, a second column of the remainder of the set of parity check columns may have a connection to a single edge of the first column and the second column may have a higher transmission priority than a third column of the remainder of the set of parity check columns without a connection to the single edge of the first column.

In some examples of the method, wireless devices, and non-transitory computer-readable medium described herein, the base graph matrix includes multiple indexed rows, a parity check node of a second column of the remainder of the set of parity check columns may have a connection to a single edge of the first column, the parity check node may be positioned in a lowest indexed row of the multiple indexed rows, and lower indexed rows of the multiple indexed rows may have higher transmission priority than higher indexed rows of the multiple indexed rows.

In some examples of the method, wireless devices, and non-transitory computer-readable medium described herein, the remainder of the set of parity check columns include three columns.

In some examples of the method, wireless devices, and non-transitory computer-readable medium described herein, at least a portion of the set of systematic bits may be mapped to a most significant bit (MSB) of a modulation constellation and at least a portion of the set of parity bits may be mapped to a least significant bit (LSB) of the modulation constellation.

In some examples of the method, wireless devices, and non-transitory computer-readable medium described herein, a dimension of the circulant identity matrix may be Z×Z, and a total size of the parity check matrix may be a size of the base graph matrix multiplied by Z.

In some examples of the method, wireless devices, and non-transitory computer-readable medium described herein, a coding rate used to encode the set of information bits into the codeword is between 0.95 and 1.

### BRIEF DESCRIPTION OF THE DRAWINGS

FIG. 1 shows an example of a wireless communication system.

FIG. 2 shows an example of a signaling configuration that supports low density parity check (LDPC) techniques in wireless communications.

FIG. 3 shows an example of base graph matrices that support LDPC techniques in wireless communications.

FIG. 4 shows an example of base graph matrices that support LDPC techniques in wireless communications.

FIG. 5 shows an example of a process flow that supports LDPC techniques in wireless communications.

FIG. 6 shows an example of a processing system that supports LDPC techniques in wireless communications.

FIG. 7 shows an example of a system including a device that supports LDPC techniques in wireless communications in accordance with one or more aspects of the present disclosure.

FIG. 8 shows an example of a system including a device that supports LDPC techniques in wireless communications in accordance with one or more aspects of the present disclosure.

FIG. 9 shows an example of a method that supports LDPC techniques in wireless communications.

Details of aspects and advantages of the subject matter in this disclosure are set forth in the drawings and accompanying descriptions. Like reference numbers and designations in the various drawings indicate like elements.

### DETAILED DESCRIPTION

A communication system may include a radio access network (RAN) that supports wireless communication. Communication of a RAN may be performed in accordance with one or more radio access technologies (RATs), including 4G, 5G, or 6G, among others, including technologies not explicitly mentioned herein. A RAT may employ access technologies (such as multiplexing technologies) including code division multiple access (CDMA), time division multiple access (TDMA), frequency division multiple access (FDMA), orthogonal FDMA (OFDMA), single-carrier FDMA (SC-FDMA), time division synchronous code division multiple access (TD-SCDMA), or discrete Fourier transform spread orthogonal frequency division multiplexing (DFT-S-OFDM), among others. A RAT may support one or more service types, including machine type communication (MTC), massive MTC (mMTC), Internet of Things (IoT), narrowband IoT (NB-IoT), reduced capability (RedCap), enhanced mobile broadband (eMBB), ultra-reliable low-latency communication (URLLC), or public safety, among others.

To support these and other target verticals, a communication system (such as a RAN) may be designed to implement one or more of a modularized functional infrastructure, a disaggregated and service-based network architecture, network function virtualization, network slicing, multi-access edge computing, spatial processing or multipath techniques, IoT or RedCap device connectivity and management, industrial connectivity, licensed and unlicensed spectrum access, sidelink or other device-to-device (D2D) direct communication (such as vehicle-to-everything (V2X)), frequency spectrum expansion, overlapping spectrum use, small cell deployments, non-terrestrial network (NTN) deployments, device aggregation, advanced duplex communication (such as sub-band full-duplex (SBFD)), multiple-subscriber implementations, high-precision positioning, radio frequency (RF) sensing, network energy savings (NES), low-power signaling and radios, or artificial intelligence or machine learning (AI/ML), among other examples.

The foregoing and other technological improvements may support use cases such as voice calls, messaging, data transfer, streaming, wireless data centers, extended reality (XR) and metaverse applications, vehicle connectivity, holographic and mixed reality communication, autonomous and collaborative robots, sensing networks, gesture monitoring, human-brain interfacing, digital twin applications, asset management, and universal coverage using non-terrestrial or aerial platforms, among other examples. As the demand for connectivity continues to increase, further improvements may be implemented, and other RATs, including 6G and beyond, may be introduced to enable new applications and use cases. The systems, methods, and devices described herein may enable one or more of the foregoing technologies or new technologies or support one or more of the foregoing use cases or new use cases.

In some wireless communication systems, wireless devices may implement error correcting codes to transmit signals over noisy communication channels, such as low density parity check (LDPC) codes. LDPC codes may be defined by a base graph (also referred to as a base graph matrix) and a lifting operation performed on the base graph using a circulant identity matrix to create a quantity of copies of the base graph. The base graph may be defined by variable nodes (e.g., columns) and check nodes (e.g., rows). Entries of the base graph may correspond to edges between the variable nodes and the check nodes. For example, if an entry of the base graph between a first variable node and a first check node has a value of one, there may be an edge between the first variable node and the first check node. Devices within the wireless communication system may implement modulation operations, such as lower-order modulation operations (quadrature phase-shift keying (QPSK) modulation) and higher-order modulation operations (e.g., quadrature amplitude modulation (QAM) modulation) to map the multiple information bits to a modulation constellation.

The base graph may be a small graph that corresponds to macroscopic properties of the code and may, in some examples, be referred to as a protograph. The lifting procedure may correspond to lifting, or replacing, each entry of the base graph with a circulant identity matrix, or an identity matrix which has been cyclically shifted. For example, the lifting procedure may copy the base graph multiple times (e.g., corresponding to a size of the identity matrices) and connect the different copies of the base graph via edge permutation. The circulant identity matrix may be a Z by Z identity matrix that is shifted in accordance with a cyclic shift value of a corresponding element of the generated base graph matrix, and where available values for Z are selected based on a quantity of edges of the generated base graph matrix. The quantity of cyclic shifts may depend on the value of the entry of the base graph (one cyclic shift for a value of “1” indicating a single edge or degree, two cyclic shifts for a value of “2” indicating two edges or degrees). In some systems, a base graph may be designed for asymptotic performance, and a device may perform a relatively large quantity of iterations to achieve reliable decoding. Base graphs in some systems may include two punctured nodes (e.g., two punctured variable nodes), as a large degree of punctured nodes may correspond to improved asymptotic performance. A punctured node may refer to a node for which the generated bits are not transmitted. However, having two punctured nodes may slow down convergence for high throughput applications. Having two punctured systematic nodes, where the content of the systematic nodes is intended to be determined during a decoding process, creates a significant processing load on the receiving device. For punctured nodes to achieve a threshold reliability, a device may perform a large quantity of iterations. Further, as throughput increases, computing resources increase, and a doubled throughput needs a corresponding doubled computing capability and doubled energy consumption (assuming a fixed processing node size). Channel coding associated with error correcting codes may consume a relatively large amount of this capability.

In some examples, a transmitting wireless device may implement probabilistic shaping techniques, such as probabilistic amplitude shaping (PAS). In M-ary QAM, M bits are encoded to form a symbol selected from a constellation of 2M possible QAM symbols, where M is a positive integer. Should each symbol in the constellation have the same probability of being transmitted, a “shaping gap” may occur that may reduce the spectral efficiency (e.g., by up to 1.53 dB). PAS may be used to reduce or eliminate this shaping gap. For example, in PAS, an outer layer of amplitude shaping may map input bits into amplitudes that have a non-uniform distribution (e.g., a Gaussian distribution). These amplitudes may be binary encoded to form a corresponding stream of information bits that are processed according to an inner layer of binary forward-error-correction (FEC) encoding to provide parity bits for a phasing of the amplitudes to create the symbol constellation. FEC encoding may be implemented using an LDPC. Puncturing systematic nodes, however, may disrupt the probabilistic shaping of the systematic nodes and accordingly the effect of the PAS.

Aspects of the subject matter described in this disclosure relate to LDPC coding techniques. More specifically, aspects of the present disclosure are related to LDPC coding techniques involve puncturing a parity check column and not puncturing a systematic LDPC column (e.g., transmitting the full systematic LDPC code). For example, the base graph matrix may not include punctured systematic nodes. The parity check column that is punctured may be a double edged node (e.g., have at least one entry with two edges or degrees). The remainder of the parity check columns may form a triangular matrix which may simplify encoding. The transmitting device may map coded bits to a modulation constellation such that systematic bits, and bits of a check node connected to the punctured column, are transmitted in higher-reliability portions of the modulation constellation,

Particular aspects of the subject matter described in this disclosure can be implemented to realize one or more of the following potential advantages. By puncturing a parity check node instead of systematic node(s), shaping of systematic nodes may be preserved. Accordingly, the effect of PAS (increasing spectral efficiency) may be preserved. To achieve the same or better asymptotic performance as puncturing multiple systematic nodes, the parity check node that is punctured may have a high degree (e.g., may have at least one entry with two edges or degrees). By forming the remainder of the parity check columns into a triangular matrix, encoding using LDPC may be simplified, thereby reducing computing resources and energy consumption associated with LDPC encoding. By mapping the systematic bits, and bits of a check node connected to the punctured column, to higher-reliability portions of the modulation constellation, the bits that are more significant for successful decoding may be more likely to be successfully received at the receiving wireless communication device, and accordingly decoding accuracy may be increased.

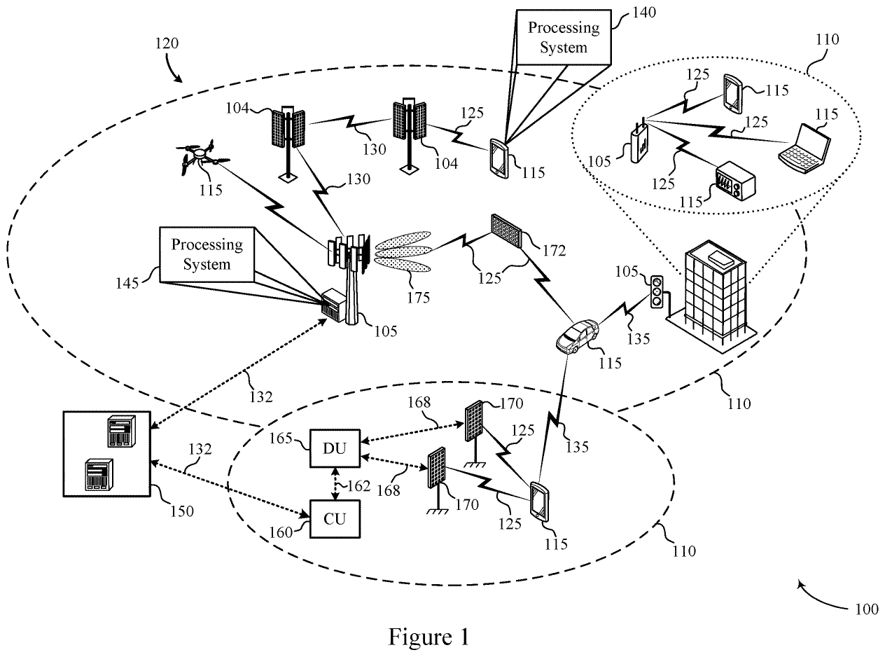

FIG. 1 shows an example of a wireless communication system 100. The wireless communication system 100 includes a core network 150 and a RAN 120 that support communication with one or more devices, such as UEs 115. A RAN 120 may include one or more network entities 105 configured to support wireless communication with the UEs 115.

The wireless communication system 100 may support communication among network entities 105 and UEs 115 in accordance with a layered protocol stack. For example, in a user plane, communication at a bearer layer, a Packet Data Convergence Protocol (PDCP) layer, or Service Data Adaption Protocol (SDAP) layer may be Internet Protocol (IP)-based. A Radio Link Control (RLC) layer may perform packet segmentation and reassembly to communicate via logical channels. A Medium Access Control (MAC) layer may perform priority handling and multiplexing of logical channels into transport channels. A MAC layer also may implement error detection techniques, error correction techniques, or retransmissions. In a control plane, a Radio Resource Control (RRC) layer may provide establishment, configuration, and maintenance of an RRC connection between UEs 115 and a network entity 105 or a core network 150, supporting radio bearers for user plane data. A Physical (PHY) layer may map transport channels to physical channels.

A core network 150 may support user authentication, access authorization, tracking, IP connectivity, and other access, routing, or mobility functions (such as via network entities 105). A core network 150 may be a 5G core (5GC) or 6G core (6GC), and may include at least one control plane entity that manages access and mobility and at least one user plane entity that routes packets or interconnects to external networks (such as a serving gateway (S-GW), a Packet Data Network (PDN) gateway (P-GW), a user plane function (UPF)).

A network entity 105 may support wireless communication in accordance with one or more coverage areas 110, and may be referred to as a network element, a network node, a RAN node, or network equipment, among other nomenclature. One or more of the network entities 105 may include or may be referred to as a base station. Depending on its capabilities, a base station may be referred to as a NodeB, an eNodeB (eNB), a next-generation NodeB or giga-NodeB (either of which may be referred to as a gNB), a 5G NB, a 6G NB, a next-generation eNB (ng-eNB), a Home NodeB, a Home eNodeB, or other suitable terminology. The wireless communication system 100 may include a heterogeneous network in which different types of network entities 105 support communication for one or more coverage areas 110 using the same or different RATs.

In some examples, a network entity 105 may be implemented in an aggregated (such as monolithic, standalone) architecture, which may utilize a protocol stack that is physically or logically integrated within one network entity 105 (such as a single physical RAN node). In some other examples, a network entity 105 may be implemented in a disaggregated architecture, which may utilize a protocol stack that is physically or logically distributed among multiple network entities 105, including in an integrated access and backhaul (IAB) network, an open RAN (O-RAN), or a virtualized RAN (vRAN). In a disaggregated architecture, a network entity 105 may include or be referred to as one or more of a central unit (CU) (such as CU 160), a distributed unit (DU) (such as DU 165), a radio unit (RU) (such as RU 170), or a combination thereof. The wireless communication system 100 may also implement a service-based architecture that provides a modular framework in which control plane functionality and common data repositories may be delivered through a set of interconnected network functions (NFs) that may access services of other NFs.

UEs 115 may be located in a coverage area 110 of one or more network entities 105, and may include or be referred to as an access terminal, a mobile station, a client device, or a subscriber unit. A UE 115 may be, include, or be coupled with a cellular phone, a wireless modem, a tablet device, a laptop computer, a wireless local loop (WLL) station, a camera, a medical or biometric device, a wearable device, a gaming device, an entertainment device, an XR device, a vehicular component or sensor, a smart meter or sensor, industrial manufacturing equipment, a Global Positioning System (GPS) or other positioning device, a robot or other device implementing artificial intelligence, a UE function of a network node, or any other wireless communication device or function that may communicate using a wireless medium.

The wireless communication system 100 may support various types of communication links among devices. For example, wireless communication between a network entity 105 and a UE 115 may be supported using one or more of a communication link 125 (such as a Uu interface), which may include downlink communication from a network entity 105 to a UE 115, uplink communication from a UE 115 to a network entity 105, or both. Direct wireless communication between UEs 115 may be supported using a communication link 135 (such as a device-to-device (D2D) communication link, a sidelink, a PC5 interface).

Communication between a network entity 105 and a core network 150 may be supported using a backhaul link 132 (such as an S1, N2, N3, NG, or other interface). In some implementations, communication between network entities 105 may be supported using a backhaul link 132 (such as an X2, Xn, or other interface) either directly (such as directly between network entities 105) or indirectly (such as via a core network 150). In some implementations (such as in a disaggregated architecture), communication between a CU 160 and a DU 165 may be supported using a midhaul link 162, and communication between a DU 165 and an RU may be supported using a fronthaul link 168. A backhaul link 132, a midhaul link 162, a fronthaul link 168, or any combination thereof may be or include one or more wired links (such as an electrical link, an optical fiber link) or one or more wireless links (such as a radio link, a wireless optical link), among other examples or combinations thereof. Wireless backhaul, midhaul, or fronthaul may be implemented via one or more IAB nodes 104, which may act as a relay using resources of an IAB donor network entity 105 (such as via a wireless link 130).

The wireless communication system 100 may include one or more of a relay 172 that may steer or reflect signals transmitted by other entities, which may support any of the described communication links. A relay 172 may include active elements or passive elements, and may be in the form of a reconfigurable intelligent surface (RIS). An RIS may include tunable reflecting antenna arrays or metasurfaces, which may be used to enhance coverage or efficiency in multipath environments.

Network entities 105 and UEs 115 each may include one or multiple antennas. Multiple antennas of such devices may be used to employ techniques such as transmit diversity, receive diversity, MIMO communication, or beamforming, and may be organized or structured as one or more antenna panels, one or more antenna groups, one or more sets of antenna elements, or one or more antenna arrays, among other examples. As used herein, the term “antenna” may refer to one or more antennas, one or more antenna panels, one or more antenna groups, one or more sets of antenna elements, or one or more antenna arrays. The term “antenna panel” may refer to a group of antennas (such as antenna elements) arranged in an array or panel, which may facilitate beamforming by manipulating parameters associated with the group of antennas. In some implementations, an antenna panel may support RF beamforming for a signal transmitted or received via an antenna port. The term “antenna module” may refer to circuitry including one or more antennas as well as one or more other components (such as filters, amplifiers, processors, beamformers) associated with integrating the antenna module into a device such as a network entity 105 or a UE 115.

Beamforming, such as directional transmission or directional reception, is a signal processing technique that may be used at a transmitting device or a receiving device (such as at a network entity 105, at a UE 115) to shape or steer a beam 175 (such as an antenna beam, a transmit beam, a receive beam) along a spatial path (such as along a direction), which may include one or more paths between a transmitting device and a receiving device. Beamforming may be achieved by combining signals communicated via multiple antenna elements of an antenna array such that signals propagating along some orientations (such as relative to the antenna array) experience constructive interference while others may experience destructive interference. Adjustments of signals communicated via the antenna elements may include a transmitting device or a receiving device applying phase offsets, amplitude offsets, or other adjustments to signals carried via (such as transmitted by, received by) antenna elements of the device, which may be defined by a beamforming weight set associated with a particular orientation (such as relative to the antenna array of the device).

Communication resources of the wireless communication system 100 (such as of a RAN 120) may refer to a resource in the frequency domain (such as a frequency resource, an RF resource), a resource in the time domain (such as a time resource), a resource in the spatial domain (such as a spatial resource, a spatial layer), or a combination thereof. The wireless communication system 100 may leverage orthogonality of such resources to convey different communications to or from different devices (such as for a communication link 125, for a communication link 135, for unicast communication, for multicast communication, for broadcast communication).

A frequency resource may refer to a frequency or range of frequencies (such as a bandwidth, a frequency channel) of a frequency band implemented for wireless communication. For example, a frequency resource may refer to a resource of a lower frequency band (such as Frequency Range 1 (FR1), between 425 MHz and 7.125 GHz), a mid-band (such as Frequency Range 3 (FR3), between 7.125 GHz and 24.25 GHz), or an upper frequency band (such as Frequency Range 2 (FR2), between 24.25 GHz and 71 GHz). Communication in the upper frequency band may be referred to as millimeter wave (mmW) communication, and communication above an upper frequency band (such as between mmW and THz frequencies, between 100 GHz and 1 THz) may be referred to as sub-Terahertz (sub-THz) communication.

A frequency resource may refer to a “carrier” (such as a frequency channel), or portion thereof, and a carrier bandwidth may be referred to as a “system bandwidth.” A carrier may be subdivided in the frequency domain, including into subcarriers, bandwidth parts (BWPs), or both. For example, a resource block (RB), such as a physical resource block (PRB), may be defined in accordance with a set of subcarriers (such as twelve consecutive subcarriers in the frequency domain), and a BWP may be configured in accordance with a set of RBs (such as a set of contiguous RBs).

A frequency resource may be configured to carry either downlink communication or uplink communication (such as in a frequency division duplexing (FDD) configuration), or may be configured to carry both downlink and uplink communication (such as in a time division duplexing (TDD) configuration, in a sub-band full duplex (SBFD) configuration). One or more numerologies for a carrier may be supported, each associated with a subcarrier spacing (SCS) and a cyclic prefix (CP). Supported numerologies may vary by frequency range (such as FR1, FR2, FR3), and a carrier may be divided into portions (such as BWPs) having the same or different numerologies. BWPs may be configured as uplink BWPs or downlink BWPs (such as by a network entity 105), including in response to network conditions (such as to allocate uplink and downlink BWPs in response to traffic conditions), device capability (such as allocating BWPs with a greater quantity of RBs to UEs 115 with relatively higher capabilities), or both. A UE 115 may be configured with a set of multiple BWPs (such as a set of uplink BWPs, a set of downlink BWPs, or both), and a single BWP of a set (such as an active UL BWP, an active DL BWP, or both) may be active at a given time, such that communication of a UE 115 is supported by active BWP(s).

A time resource may refer to a duration of a frame (such as a radio frame, a frame structure), or portion thereof. For example, a frame may span a duration of 10 ms, and each frame may be identified by a system frame number (SFN). A frame may be subdivided in the time domain, including into subframes, slots, mini-slots, or a combination thereof. Slots or mini-slots may each include a respective quantity of symbols (such as symbol durations, symbol periods, OFDM symbols), which may be a function of a configured CP. A duration of a symbol is a function of the SCS or frequency band of operation.

A spatial resource may refer to an antenna, an antenna direction, an antenna port, a signal direction (such as a beamforming direction), or other resource that supports spatial orthogonality. A device (such as a network entity 105, a UE 115) may perform communications of a given frequency resource and time resource with a single spatial resource (such as communication without regard to spatial orthogonality). Additionally, or alternatively, a device may implement multiple spatial resources to support multiple signal streams using resources that are overlapping in the time and frequency domains (such as to support MIMO techniques).

Signals of the wireless communication system 100 (such as of a RAN 120) may be communicated using one or more resource elements (REs), and an RE may refer to a resource that corresponds to one subcarrier in the frequency domain and one symbol in the time domain. An RE may be used to convey a modulation symbol corresponding to one or more bits of information (such as of a physical channel, of a reference signal) in accordance with a modulation scheme. For example, a QPSK or QAM technique may be implemented to communicate one or more bits that are distinguished in accordance with phase components, amplitude components, or both of a signal conveyed using a RE. A quantity of bits carried by an RE may depend on an order of the modulation scheme, and a relatively higher order may correspond to a relatively higher rate of communication. A device may support communication of REs using multiple subcarriers concurrently by implementing multi-carrier modulation (MCM) techniques such as orthogonal frequency division multiplexing (OFDM) or discrete Fourier transform spread OFDM (DFT-S-OFDM), among others.

Physical channels may carry information using modulation symbols conveyed by corresponding REs. Physical shared channels (such as for communicating user data) may include a physical downlink shared channel (PDSCH) for communicating user data in a downlink direction and a physical uplink shared channel (PUSCH) for communicating user data in an uplink direction. Physical control channels (such as for managing communication via physical channels) may include a physical downlink control channel (PDCCH) for communicating downlink control information (DCI) and a physical uplink control channel (PUCCH) for communicating uplink control information (UCI). A network entity 105 may indicate (such as schedule, allocate) communication resources for a UE 115 using DCI, including indicating downlink resources of a PDSCH (such as in accordance with a downlink grant), uplink resources of a PUSCH (such as in accordance with an uplink grant), or a combination thereof. A control region (such as a control resource set (CORESET)) for a physical control channel may be configured in accordance with a pattern of REs in the time and frequency domains, and one or more control regions may be configured for a set of UEs. A UE 115 may monitor control regions for control information according to one or more search space sets, which may include a common search space set (such as for sending control information to one or more UEs 115), UE-specific search space sets (such as for sending control information to a UE 115), or a combination thereof. A physical broadcast channel (PBCH) may be used to broadcast parameters to UEs 115 to synchronize with a network entity 105 and establish communications (such as to establish a communication link 125).

Reference signals may be communicated to establish reference characteristics (such as a frequency reference, a temporal reference, a spatial reference, a signal quality reference) between devices of a RAN 120, which may support communication using physical channels. Reference signals communicated between network entities 105 and UEs 115 may include synchronization signals (such as a primary synchronization signal (PSS), a secondary synchronization signal (SSS)) that support temporal synchronization, channel state information-reference signals (CSI-RSs) that support evaluating downlink channel characteristics, sounding reference signals (SRSs) that support evaluating uplink channel characteristics, demodulation reference signals (DMRSs) that support demodulation, or phase tracking reference signals (PTRSs) for evaluating oscillator characteristics, among others. Network entities 105 and UEs 115 may receive and measure transmitted reference signals to support one or more of these and other functions.

Devices in the wireless communication system 100 (such as network entities 105, UEs 115) may modulate and code information prior to transmission of a signal (such as of a physical channel). A modulation and coding scheme (MCS) may define how modulation and coding is to be performed, which may include an implementation in accordance with a modulation order and a target code rate. A code rate may be achieved using a channel coding scheme such as FEC (such as to add redundancy). Examples of FEC include block codes, convolutional codes, and linear error-correcting codes. At a receiver (such as to demodulate modulation symbols of a physical channel), a decoder may employ probabilistic or iterative techniques to perform soft decision-making, and code blocks (CBs) for bit streams may employ a check code (such as a cyclic redundancy check (CRC) code, an LDPC) to detect and correct decoding errors.

The UEs 115 and the network entities 105 may support retransmissions of data to increase the likelihood that data is received successfully. Hybrid automatic repeat request (HARQ) feedback is one technique for increasing the likelihood that data is received correctly via a communication link (e.g., the communication link(s) 125, a D2D communication link 135). HARQ may include a combination of error detection (e.g., using a CRC), FEC, and retransmission (e.g., automatic repeat request (ARQ)). HARQ may improve throughput at the MAC layer in relatively poor radio conditions (e.g., low signal-to-noise conditions). In some examples, a device may support same-slot HARQ feedback, where the device may provide HARQ feedback in a specific slot for data received via a previous symbol of the slot. In some other examples, the device may provide HARQ feedback via a subsequent slot or according to some other time interval.

Devices of the wireless communication system 100 may be configured to support one or more aspects of the described techniques for LDPC techniques in wireless communications. For example, a UE 115 may include a processing system 140, and a network entity 105 may include a processing system 145, each of which may be configured to cause the respective device to perform (such as being configured as means for performing) one or more of the described operations. By configuring a processing system 140, a processing system 145, or a combination thereof in accordance with the described techniques, the wireless communication system 100 (such as the RAN 120) may support LDPC coding techniques that preserve probabilistic shaping, simplify encoding and decoding, and provide faster convergence, and may thereby reduce processing resources. For example, a transmitting wireless device, such as a UE 115 in sidelink or uplink or a network entity 105 in downlink, may transmit data as a codeword encoded in accordance with an error correcting code such as LDPC. The transmitting wireless device may use PAS to increase spectral efficiency. The transmitted wireless device may puncture a parity check node of the LDPC base graph matrix that has a high degree to provide faster convergence. Puncturing the parity check node instead of systematic node(s) may preserve the effect of the PAS. The unpunctured parity check columns of the base graph matrix (e.g., the remaining parity check columns) may form a triangular matrix, which may simplify encoding and decoding using LDPC.

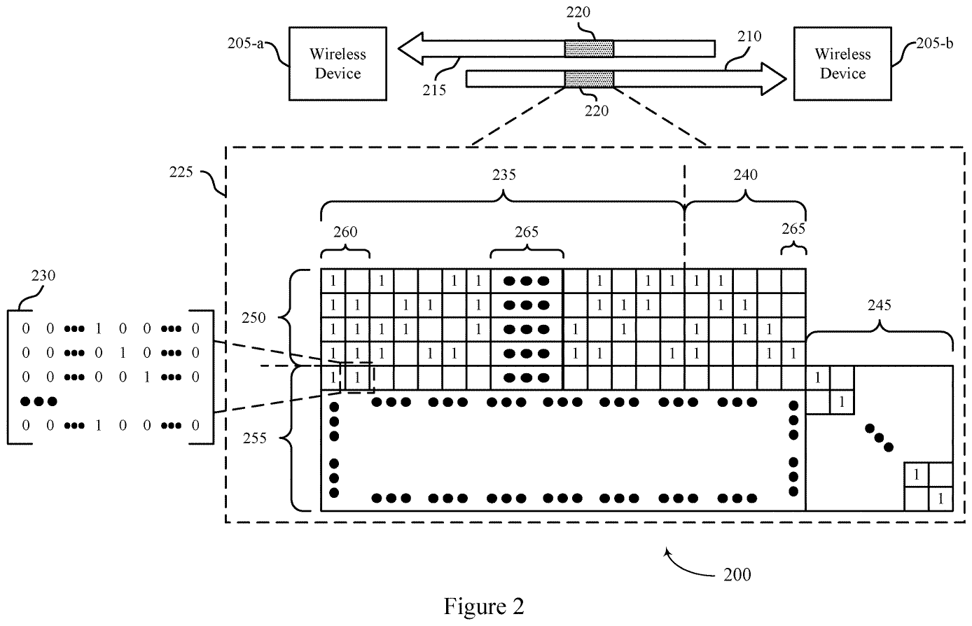

FIG. 2 shows an example of a signaling configuration 200 that supports LDPC techniques in wireless communications. The signaling configuration 200 may implement or may be implemented by aspects of the wireless communication system 100. For example, the signaling configuration 200 may include a wireless device 205-a and a wireless device 205-b, which may be examples of corresponding devices described herein (e.g., a network entity 105, a UE 115). The wireless device 205-a may communicate with the wireless device 205-b via the communication link 210 and the communication link 215. The communication link 210 and the communication link 215 may be either the uplink or the downlink, and in some cases may be a sidelink connection. A device transmitting a signal 220, or a message, (e.g., in the uplink, downlink, or sidelink) may be referred to as a transmitting device, and a device receiving the signal 220 (e.g., in the uplink, downlink, or sidelink) may be referred to as a receiving device.

The signaling configuration 200 may implement FEC to reduce transmission errors when performing communications over unreliable or noisy channels. In some examples, the wireless device 205-a may be a transmitting device and may transmit a signal to the wireless device 205-b, which may be a receiving device, according to an error correction code. For example, the wireless device 205-a may transmit a signal 220 using an LDPC code (e.g., a quasi-cyclic (QC) LDPC code). The LDPC code may be described or defined by a base graph 225 (e.g., a protograph) and a lifting matrix 230. The base graph 225 may capture (e.g., represent) the macroscopic properties of the LDPC code (e.g., a threshold).

In some examples, the base graph 225 may be represented as a matrix (e.g., a base matrix). The base graph 225 may include multiple columns and multiple rows. Each column of the multiple columns of the base graph 225 may denote (e.g., be defined as) a variable node, and each row of the multiple rows of the base graph 225 may denote (e.g., may be defined as) a check node. The multiple variable nodes of the base graph 225 may include multiple information nodes 235, multiple core parity nodes 240, and multiple extension parity nodes 245. The multiple check nodes of the base graph 225 may include multiple core check nodes 250 and multiple extension check nodes 255. Each variable node may be associated with a degree, which may denote a quantity of check nodes associated with each variable node. For example, the degree associated with a variable node may indicate that the variable node is associated with a quantity of edges of the base graph 225 (e.g., non-zero elements of the variable node). In some cases, one or more variable nodes of the base graph 225 may be punctured information nodes (e.g., a non-transmitted node). For example, the first and second nodes 260 may be punctured information nodes Additionally, or alternatively, the multiple information nodes 235 may include one or more special extension check nodes 265.

The LDPC code may be further described by a lifting matrix 230. For example, the LDPC code may be described by a circulant identity matrix, and the wireless device 205-a, the wireless device 205-b, or both the wireless device 205-a and the wireless device 205-b may lift (e.g., perform a lifting operation) each entry of the base graph 225 according to the circulant identity matrix, which may be a Z by Z matrix (e.g., where Z≤384). The cyclic shift associated with the circulant identity matrix may be indicated by a non-zero value in the base graph 225. For example, a value of “1” in a particular element of the base graph may indicate a single cyclic shift is applied to the element when lifting, and a value of “2” may indicate two cyclic shifts are applied to the element when lifting. In some examples, each variable node of the base graph 225 may be associated with a quantity of coded bits associated with the LDPC code, and the dimensions of the lifting matrix 230 (e.g., width, height, or both) may be equal to the quantity of coded bits. In such examples, the wireless device 205-b, or both the wireless device 205-a and the wireless device 205-b, may create a quantity of copies of the base graph 225 equal to the quantity of coded bits and may connect the quantity of copies of the base graph 225 via edge permutation. A total block length may be the base graph 225 size times the lift value (Z). By performing the lifting operation, the wireless device 205-b, or both the wireless device 205-a and the wireless device 205-b, may preserve a degree distribution of each coded bit.

In some aspects, the wireless device 205-a and the wireless device 205-b may perform a higher-order modulation operation (e.g., 256QAM) to map the coded bits to a modulation constellation in accordance with a systematic bit prioritized mapping (SBPM) scheme. The SBPM scheme may map the systematic portion of the coded bits (e.g., information bits) to one or more most significant bits (MSBs) of the modulation constellation, and may map the non-systematic portion of the coded bits (e.g., parity bits) to one or more least significant bits (LSBs) of the modulation constellation. The MSBs may have higher reliability than the LSBs. Such techniques may provide that copies of the same variable nodes in the base graph 225 experience similar channel reliabilities and different variable nodes in the base graph 225 may experience different channel reliabilities, and thus may generally improve the decoding threshold of QC LDPC.

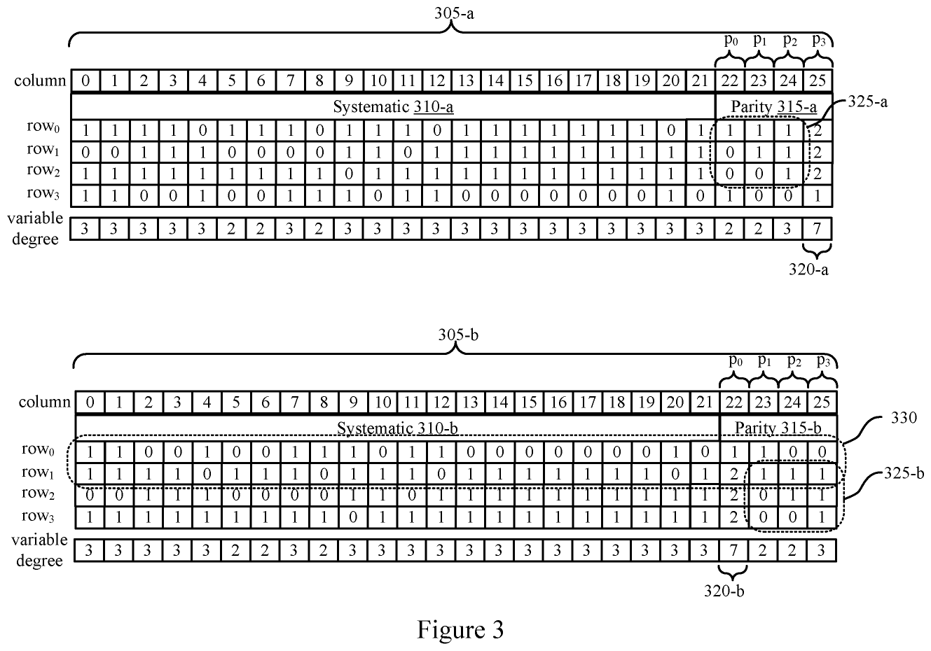

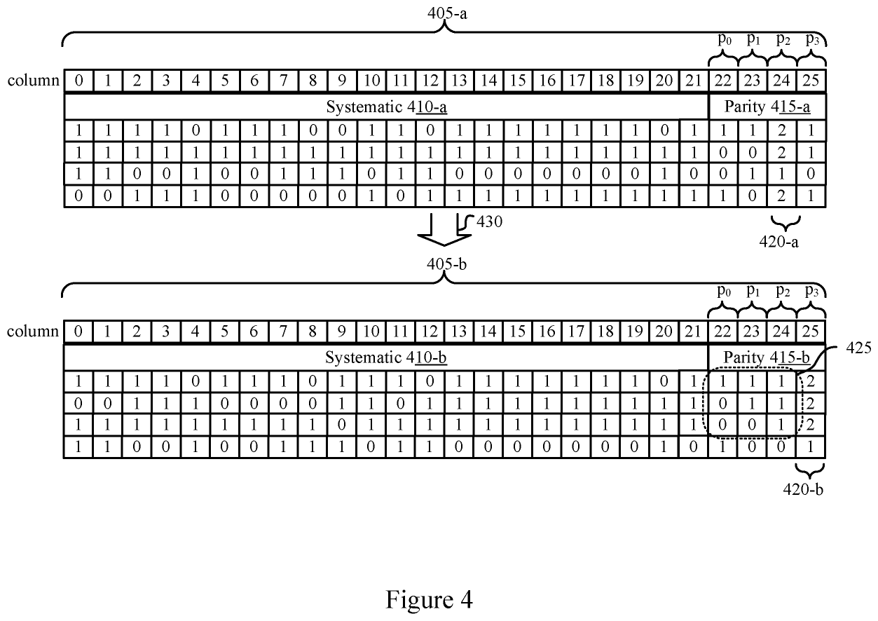

In some examples, the wireless device 205-a and the wireless device 205-b may perform shaping techniques, such as PAS to improve spectral efficiency. For example, some constellation symbols may be used with a higher probability than other constellation symbols. For example, in PAS, lower amplitude constellation symbols may have a higher probability than (and thus may be used more frequently than) higher amplitude constellation symbols. To preserve such shaping, in some examples, the systematic nodes (e.g., the multiple information nodes 235) may not be punctured and a parity node (e.g., one of the multiple core parity nodes 240) may be punctured, as described with reference to FIGS. 3-4.

FIG. 3 shows an example of a base graph matrix 305-a and a base graph matrix 305-b that support LDPC techniques in wireless communications. The base graph matrix 305-a and the base graph matrix 305-b may implement or may be implemented by aspects of the wireless communication system 100 or the signaling configuration 200. For example, the base graph matrix 305-a and the base graph matrix 305-b may be example base graph matrices used for LDPC encoding by the wireless device 205-a or the wireless device 205-b (e.g., for transmission the signal 220).

As described herein, a base graph matrix 305 may include systematic columns 310 (e.g., systematic nodes) and parity check columns 315 (e.g., parity check nodes). For example, the base graph matrix 305-a includes systematic columns 310-a and parity check columns 315-a, and the base graph matrix 305-b includes systematic columns 310-b and parity check columns 315-b. In the examples of FIG. 3, the systematic columns 310 include columns 0-21 and the parity check columns include columns 22-25. For example, column 22 may correspond to a parity check column p₀, column 23 may correspond to a parity check column p₁, column 24 may correspond to a parity check column p₂, and column 25 may correspond to a parity check column p₃. In the base graph matrix 305-a and the base graph matrix 305-b, a non-zero element indicates that the corresponding variable node (e.g., column) is connected to the corresponding check node (e.g., row of the base graph matrix). The value in each element may indicate the quantity of cyclic shifts that will be applied in the lifting operation (e.g., a value of “1” in a particular element of the base graph may indicate a single cyclic shift is applied to the element when lifting, and a value of “2” may indicate two cyclic shifts are applied to the element when lifting). Each variable node may be associated with a degree, which may denote the quantity of check nodes associated with each variable node. For example, FIG. 3 shows the degree of each variable node (e.g., the degree for each systematic column 310 and each parity check column 315) of the base graph matrix 305-a and the base graph matrix 305-b.

In the base graph matrix 305-a, the column 25 has a degree of 7 (e.g., multiple elements of column 25 have elements with double edges (e.g., values of “2”). Accordingly, the column 25 may be the punctured column 320-a (e.g., the punctured variable node) for the base graph matrix 305-a. The remainder of the parity check columns 315-a (e.g., column 22, column 23, and column 24) may form a triangular matrix 325-a. The triangular matrix 325-a may be an approximate upper triangular matrix, meaning that the (L−1)×(L−1) submatrix of the remaining parity columns is triangular (where L=4 in the base graph matrix 305-a to denote the four parity check columns 315-a), and one additional row/column is appended to the (L−1)×(L−1) triangular submatrix.

Similarly, in the base graph matrix 305-b, the column 22 has a degree of 7 (e.g., multiple elements of column 22 have elements with double edges (e.g., values of “2”). Thus, the column 22 may be the punctured column 320-b (e.g., the punctured variable node) for the base graph matrix 305-b. The remainder of the parity check columns 315-b (e.g., column 23, column 24, and column 25) may form a triangular matrix 325-b. The triangular matrix 325-b may be an approximate lower triangular matrix, meaning that the (L−1)×(L−1) submatrix of the remaining parity columns is triangular (where L=4 in the base graph matrix 305-b to denote the four parity check columns 315-b), and one additional row/column is appended to the (L−1)×(L−1) triangular submatrix.

In some examples, the highest degree parity check column may be positioned in column 23 or column 24 (e.g., at p1 or p2), and the remainder of the parity check columns may form an approximate upper or lower triangular matrix.

An approximate triangular matrix (e.g., either upper as in the base graph matrix 305-a or lower as in the base graph matrix 305-b) enables the encoder to apply back substitution instead of computing the inverse of the lifted (L−1)×(L−1)×Z lifted graph. In some examples, row and/or column permutations of the base graph matrix may be performed (e.g., as described with reference to FIG. 4) to achieve an upper or lower approximate triangular matrix in the remaining parity check columns.

For example, in the base graph matrix 305-a where there are four parity check columns, the encoder may calculate 4×Z parity bits (where the circulant identity matrix used to lift the base graph matrix is a Z by Z matrix). LDPC encoding may generate systematic bits and parity check bits to satisfy equations 1, 2, 3, and 4. In equations 1, 2, 3, and 4, t₀, t₁, t₂, and t₃ correspond to the linear combinations of the systematic parts for each row (e.g., row 0, row 1, row 2, and row 3, respectively) of the base graph matrix 305-a. In equations 1, 2, 3, and 4: c₀ corresponds to the cyclic shift applied to row 0 column 22; c₁ corresponds to the cyclic shift applied to row 0 column 23; c₂ corresponds to the cyclic shift applied to row 0 column 24; c₃ and c₄ corresponds to the two cyclic shifts applied to row 0 column 25 (as the value in row 0 column 25 is “2” two cyclic shifts are applied); c₅ corresponds to the cyclic shift applied to row 1 column 23; c₆ corresponds to the cyclic shift applied to row 1 column 24; c₇ and c₈ corresponds to the two cyclic shifts applied to row 1 column 25 (as the value in row 1 column 25 is “2” two cyclic shifts are applied); c₉ corresponds to the cyclic shift applied to row 2 column 24; c₁₀ and c₁₁ corresponds to the two cyclic shifts applied to row 2 column 25 (as the value in row 2 column 25 is “2” two cyclic shifts are applied); c₁₂ corresponds to the cyclic shift applied to row 3 column 22; and c₁₃ corresponds to the cyclic shift applied to row 3 column 25. Thus, in equations 1, 2, 3, and 4, p₀[c₀] corresponds to the bit values of the lifted matrix corresponding to row 0 column 22; p₁[c₁] corresponds to the bit values of the lifted matrix corresponding to row 0 column 23; p₂[c₂] corresponds to the bit values of the lifted matrix corresponding to row 0 column 24; p₃[c₃,c₄] corresponds to the bit values of the lifted matrix corresponding to row 0 column 25; p₁[c₅] corresponds to the bit values of the lifted matrix corresponding to row 1 column 23; p₂[c₆] corresponds to the bit values of the lifted matrix corresponding to row 1 column 24; p₃[c₇,c₈] corresponds to the bit values of the lifted matrix corresponding to row 1 column 25; p₂[c₉] corresponds to the bit values of the lifted matrix corresponding to row 2 column 24; p₃[c₁₀,c₁₁] corresponds to the bit values of the lifted matrix corresponding to row 2 column 25; p₀[c₁₂] corresponds to the bit values of the lifted matrix corresponding to row 3 column 22; and p₃[c₁₃] corresponds to the bit values of the lifted matrix corresponding to row 3 column 25.

t₀+p₀[c₀]+p₁[c₁]+p₂[c₂]+p₃[c₃,c₄]=0 (1)

t₁+p₁[c₅]+p₂[c₆]+p₃[c₇,c₈]=0 (2)

t₂+p₂[c₉]+p₃[c₁₀,c₁₁]=0 (3)

t₃+p₀[c₁₂]+p₃[c₁₃]=0 (4)

The encoder (e.g., at the transmitting wireless device) may compute p₃ (e.g., the punctured node) as a function of t₀, t₁, t₂, and t₃. Accordingly, p₂, p₁, and p₀ may be rewritten and thus computed in terms of p₃ as shown below in equations 5 through 9.

p₂[c₆]=(t₂+p₃[c₁₀,c₁₁])_{C6-C9} (5)

p₁[c₁]=(t₁+p₂[c₆]+p₃[c₇,c₈])_{C1-C5}=(t₁+(t₂+p₃[c₁₀,c₁₁])_{C6-C9}+p₃[c₇,c₈])_{C1-C5} (6)

p₀[c₁₂]=(t₀+p₁[c₁]+p₂[c₂]+p₃[c₃,c₄])_{C12-C0}=(t₀+(t₁+(t₂+p₃[c₁₀,c₁₁])_{C6-C9}+p₃[c₇,c₈])_{C1-C5}+(t₂+p₃[c₁₀,c₁₁])_{C2-C9}+p₃[c₃,c₄) (7)

p₃[c₁₃]=t₃+p₀[c₁₂]=t₃+(t₀+(t₁+(t₂+p₃[c₁₀,c₁₁])_{C6-C9}+p₃[c₇,c₈])_{C1-C5}+(t₂+p₃[c₁₀,c₁₁])_{C2-C9} (8)

p₃[c₁₃]+p₃[c₁₀+c₆−c₉+c₁−c₅+c₁₂−c₀]+p₃[c₁₁+c₆−c₉+c₁−c₅+c₁₂−c₀]+p₃[c₁₀+p₃[c₇+c₁−c₅+c₁₂−c₀]+p₃[c₈+c₁−c₅+c₁₂−c₀]+p₃[c₃+c₁₂−c₀]+p₃[c₄+c₁₂−c₀]=f(t₀,t₁,t₂,t₃) (9)

Thus, because the remainder of the parity check columns are in a triangular matrix form, once the values of p₃ are determined in accordance with equation 9, the encoder (e.g., at the transmitting wireless device) may perform back substitution to determine, for row 2, the value of p₂ based on t₂ and the value of p₃. Then the encoder may perform back substitution to determine, for row 1, the value of p₁ based on t₁ and the values of p₂ and p₃. Then the encoder may perform back substitution to determine, for row 0, the value of p₀ based on t₀ and the values of p₁, p₂ and p₃. Thus, the encoder may determine the inverse of the sub of cyclic shift matrices, p₃=(C₁+C₂ +. . . +C₉)⁻¹b, and may compute the remainder of the parity check values (p₂, p₁, and p₀) using back-substitution (e.g., using simple cyclic shifts and exclusive OR (XOR)), which is simplified due to the triangular matrix form (e.g., as only one variable is unknown for each column). Similar operations may be performed for a lower triangular matrix as in the base graph matrix 305-b. For example, in the base graph matrix 305-b, the encoder may first solve for p₀, and then may perform back substitution to solve for p₃ based on the values of t₃ and p₀, then may perform back substitution to solve for p₂ based on the values of t₂, p₀, and p₃, then may perform back substitution to solve for p₁ based on the values of t₁, p₀, p₂, and p₃.

In some examples, the columns that have a connection to the single edge in the punctured node (e.g., the punctured column 320) may be transmitted with a higher priority (e.g., transmitted earlier and/or in the more significant bits or the more reliable bits) as such columns may be used to recover the punctured column 320. For example, in the base graph matrix 305-a, column 22 may have a connection to the single edge in the punctured column 320-a (e.g., p₃), and thus column 22 may have a higher transmission priority than columns 23 or 24.

In some examples, the check node (e.g., rows of the base graph matrix) that is connected to the punctured node (e.g., the punctured column 320) by a single edge may be placed in the first row (e.g., row 0) of the base graph matrix to support natural order decoding. For example, at a high code rate (e.g., R>22/23=0.956), one or two parity nodes (e.g., parity check columns 315) of the base graph matrix may be used (and the remainder may not be used). For example, only the elements of the rectangle 330 may be transmitted at a high code rate. Placing the check node (e.g., rows of the base graph matrix) that is connected to the punctured node (e.g., the punctured column 320) by a single edge as shown in the base graph matrix 305-b may assist in recovering the punctured node in such scenarios. Repositioning of the rows may be achieved via row permutation as described herein. The punctured column 320 may be positioned in any of the parity check columns (e.g., as the values corresponding to the punctured column 320 are not transmitted).

The LDPC code that includes the full systematic code and a punctured parity check column may be decoded at a higher code rate than NR LDPC. For example, NR may specify that a UE 115 may skip decoding a transport block in an initial transmission if the effective channel code rate is higher than 0.95, where the effective channel code rate is defined as the number of downlink information bits (including CRC bits) divided by the number of physical channel bits on PDSCH (e.g., due to two systematic/information nodes being punctured in NR LDPC). With the full systematic code and a punctured parity check column, as described herein, theoretically a UE 115 may decode as long as the coding rate is below 1 (e.g., R<1).

FIG. 4 shows an example of a base graph matrix 405-a and a base graph matrix 405-b that support LDPC techniques in wireless communications. The base graph matrix 405-a and the base graph matrix 405-b may implement or may be implemented by aspects of the wireless communication system 100, the signaling configuration 200, the base graph matrix 305-a, or the base graph matrix 305-b. For example, the base graph matrix 405-a and the base graph matrix 405-b may be example base graph matrices used for LDPC encoding by the wireless device 205-a or the wireless device 205-b (e.g., for transmission the signal 220).

As described herein, a base graph matrix 405 may include systematic columns 410 (e.g., systematic nodes) and parity check columns 415 (e.g., parity check nodes). For example, the base graph matrix 405-a includes systematic columns 410-a and parity check columns 415-a, and the base graph matrix 405-b includes systematic columns 410-b and parity check columns 415-b. In the examples of FIG. 4, the systematic columns 410 include columns 0-21 and the parity check columns include columns 22-25. For example, column 22 may correspond to a parity check column p₀, column 23 may correspond to a parity check column p₁, column 24 may correspond to a parity check column p₂, and column 25 may correspond to a parity check column p₃. In the base graph matrix 405-a and the base graph matrix 405-b, a non-zero element indicates that the corresponding variable node (e.g., column) is connected to the corresponding check node (e.g., row of the base graph matrix). The value in each element may indicate the quantity of cyclic shifts that will be applied in the lifting operation (e.g., a value of “1” in a particular element of the base graph may indicate a single cyclic shift is applied to the element when lifting, and a value of “2” may indicate two cyclic shifts are applied to the element when lifting).

The base graph matrices may be rearranged via a transformation 430 such as via row and/or column permutation. For example, as described herein, a base graph matrix applied to a set of information bits to generate systematic bits and parity bits may include a triangular matrix in a remainder of the parity check columns other than the punctured column 420 to simplify LDPC encoding using the base graph matrix. For example, the base graph matrix 405-a does not form a triangular matrix in columns 22, 23, and 25 (where column 24 is the punctured column 420-a). The transformation 430 may be applied to the base graph matrix 405-a to generate the base graph matrix 405-b where columns 22, 23, and 24 form a triangular matrix 425 and column 25 is the punctured column 420-b (with one or more elements having a value of “2”). For example, the transformation 430 may involve a row ordering operation of 1-4-2-3 and a column ordering operation of 2-1-4-3.

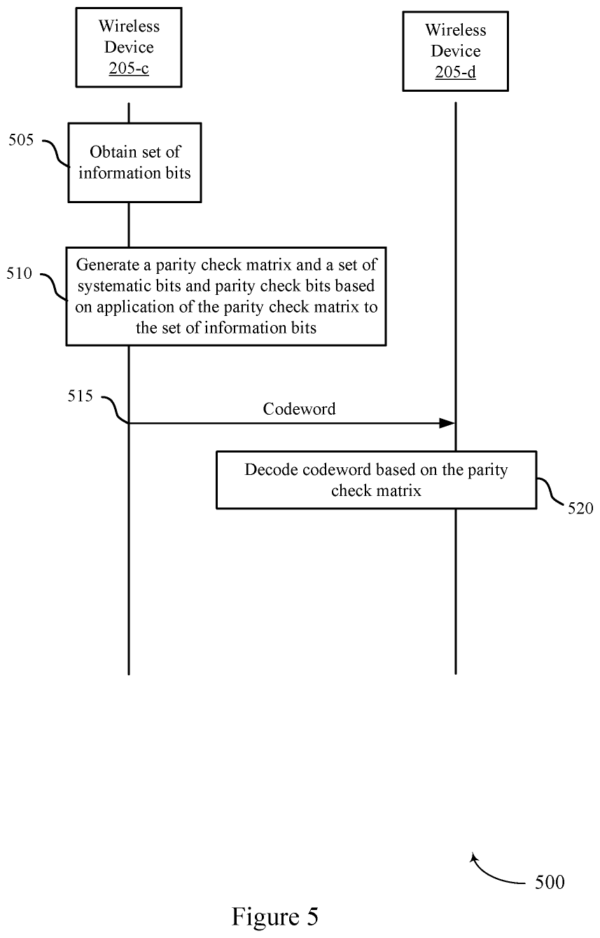

FIG. 5 shows an example of process flow 500 that supports LDPC techniques in wireless communications. The process flow 500 may implement or be implemented by the wireless communication system 100, the signaling configuration 200, the base graph matrix 305-a, the base graph matrix 305-b, the base graph matrix 405-a, or the base graph matrix 405-b. For example, the process flow 500 may include a wireless device 205-c and a wireless device 205-d, which may be examples of wireless devices 205 described herein. In the following description of the process flow 500, the operations between the wireless device 205-c and the wireless device 205-d may be performed in different orders or at different times. Some operations may also be left out of the process flow 500, or other operations may be added.

At 505, the wireless device 205-c may obtain a set of information bits for transmission to the wireless device 205-d.

At 510, the wireless device 205-c may generate a parity check matrix based on the set of information bits. The parity check matrix may be associated with (e.g., generated from) a base graph matrix. The base graph matrix may include a set of systematic columns (e.g., systematic columns 310 as described with reference to FIG. 3) used to generate a set of systematic bits corresponding to the set of information bits via application of the parity check matrix to the set of information bits. The base graph matrix may include a set of parity check columns (e.g., parity check columns 315 as described with reference to FIG. 3) used to generate a set of parity bits from the set of information bits via application of the parity check matrix to the set of information bits. The parity check matrix may be generated by applying a circulant identity matrix to each entry of the base graph matrix. At least a first column of the set of parity check columns may be a punctured column, and a remainder of the set of parity check columns may form a triangular matrix (e.g., an approximate upper triangular matrix or an approximate lower triangular matrix as described herein).

At 515, the wireless device 205-c may transmit, to the wireless device 205-d, a codeword that includes the set of systematic bits and the set of parity bits. Only non-punctured columns associated with the base graph matrix may be transmitted at 515.

At 520, the wireless device 205-d may decode the codeword (e.g., may extract the set of systematic bits and the set of parity bits) and may verify the decoding accuracy based on the parity check matrix.

In some examples, the first column may include at least one value greater than one (e.g., may have an element with a value of “2” or more). In some examples, the circulant identity matrix is a Z by Z identity matrix that is shifted in accordance with a cyclic shift value of a corresponding element of the base graph matrix, and available cyclic shift values for Z are selected based on a quantity of edges of the base graph matrix, where an edge of the base graph matrix corresponds to an element of the base graph matrix that has an adjacent non-zero element of the base graph matrix. In some examples, respective values of respective elements of the base graph matrix corresponds to a quantity of cyclic shift values to apply to the respective elements.

In some examples, the wireless device 205-c may perform one or more row permutations or column permutations on an original base graph matrix to generate the base graph matrix that forms the triangular matrix. For example, such row or column permutations may be performed to form the triangular matrix.

In some examples, a second column of the remainder of the set of parity check columns has a connection to a single edge of the first column, and the second column has a higher transmission priority than a third column of the remainder of the set of parity check columns without a connection to the single edge of the first column.

In some examples, the base graph matrix may include multiple indexed rows, a parity check node of a second column of the remainder of the set of parity check columns has a connection to a single edge of the first column, the parity check node is positioned in a lowest indexed row of the multiple indexed rows, and lower indexed rows of the multiple indexed rows have higher transmission priority than higher indexed rows of the multiple indexed rows.

In some examples, the remainder of the set of parity check columns include three columns (e.g., L=4 for the parity check columns).

In some examples, at least a portion of the set of systematic bits are mapped to an MSB of a modulation constellation, and at least a portion of the set of parity bits are mapped to an LSB of the modulation constellation.

In some examples, a dimension of the circulant identity matrix is Z×Z (e.g., the circulant identity matrix is a Z by Z matrix), and a total size of the parity check matrix is a size of the base graph matrix multiplied by Z.

In some examples, a coding rate used to encode the set of information bits into the codeword is between 0.95 and 1.

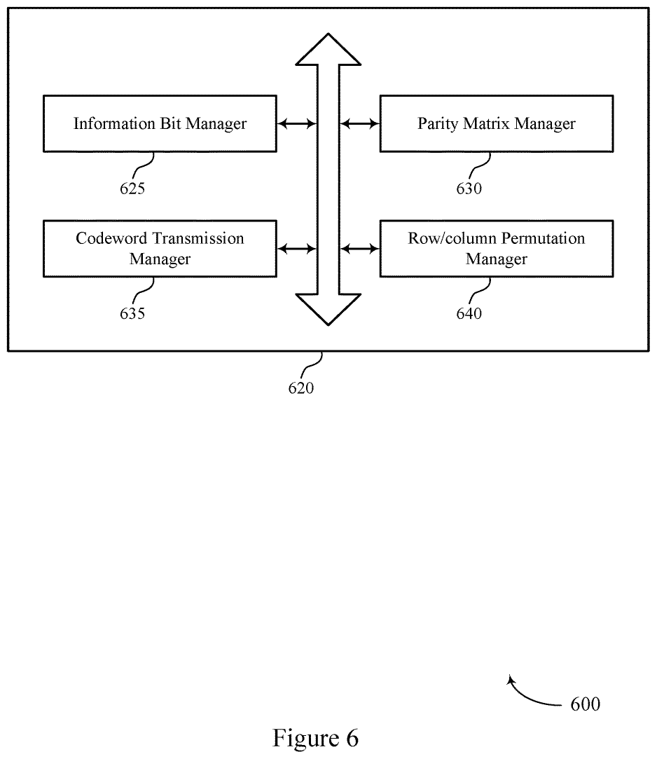

FIG. 6 shows an example 600 of a processing system 620 that supports LDPC techniques in wireless communications. A processing system 620 may be an example of a processing system 145 (such as network entity 105) and may include an information bit manager 625, a parity matrix manager 630, a codeword transmission manager 635, a row/column permutation manager 640, or any combination thereof. A processing system 620, or various component thereof, may be an example of means for performing (such as a means for causing a network entity 105 to perform) various techniques described herein.

The information bit manager 625 may be configured to cause the UE 115 or the network entity 105 to obtain a set of information bits to be transmitted from the wireless device. The parity matrix manager 630 may be configured to cause the UE 115 or the network entity 105 to generate a parity check matrix based on the set of information bits, the parity check matrix associated with a base graph matrix, where the base graph matrix includes a set of systematic columns used to generate a set of systematic bits corresponding to the set of information bits via application of the parity check matrix to the set of information bits, where the base graph matrix includes a set of parity check columns used to generate a set of parity bits from the set of information bits via application of the parity check matrix to the set of information bits, the parity check matrix generated by applying a circulant identity matrix to each entry of the base graph matrix, where at least a first column of the set of parity check columns is a punctured column and a remainder of the set of parity check columns form a triangular matrix. The codeword transmission manager 635 may be configured to cause the UE 115 or the network entity 105 to transmit a codeword including the set of systematic bits and a portion of the set of parity bits generated using non-punctured parity check columns of the set of parity check columns.

In some examples, the first column includes at least one value greater than one.

In some examples, the circulant identity matrix is a Z by Z identity matrix that is shifted in accordance with a cyclic shift value of a corresponding element of the base graph matrix, and where available cyclic shift values for Z are selected based on a quantity of edges of the base graph matrix, where an edge of the base graph matrix corresponds to an element of the base graph matrix that has an adjacent non-zero element of the base graph matrix.

In some examples, respective values of respective elements of the base graph matrix corresponds to a quantity of cyclic shift values to apply to the respective elements.

In some examples, the row/column permutation manager 640 may be configured to cause the UE 115 or the network entity 105 to perform one or more row permutations or column permutations on an original base graph matrix to generate the base graph matrix that forms the triangular matrix.

In some examples, a second column of the remainder of the set of parity check columns has a connection to a single edge of the first column. In some examples, the second column has a higher transmission priority than a third column of the remainder of the set of parity check columns without a connection to the single edge of the first column.

In some examples, the base graph matrix includes multiple indexed rows. In some examples, a parity check node of a second column of the remainder of the set of parity check columns has a connection to a single edge of the first column. In some examples, the parity check node is positioned in a lowest indexed row of the multiple indexed rows. In some examples, lower indexed rows of the multiple indexed rows have higher transmission priority than higher indexed rows of the multiple indexed rows.

In some examples, the remainder of the set of parity check columns include three columns.

In some examples, at least a portion of the set of systematic bits are mapped to an MSB of a modulation constellation. In some examples, at least a portion of the set of parity bits are mapped to an LSB of the modulation constellation.

In some examples, a dimension of the circulant identity matrix is Z×Z, and a total size of the parity check matrix is a size of the base graph matrix multiplied by Z.

In some examples, a coding rate used to encode the set of information bits into the codeword is between 0.95 and 1.

By including or configuring a processing system 620 for operation in a processing system 620 as described herein, the processing system 620 may support techniques for faster convergence for decoding LDPC codes, which may provide for efficient processing using less processing resources per decoding of CBs

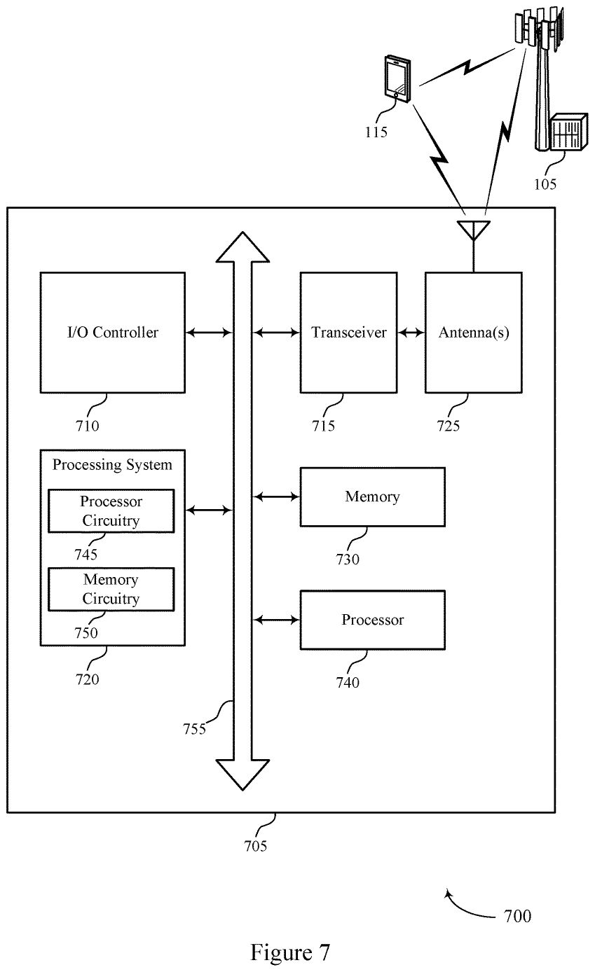

FIG. 7 shows an example of a system 700 including a device 705 that supports LDPC techniques in wireless communications. The device 705 may be an example of or include components of UE 115. The device 705 may communicate (such as wirelessly) with one or more other devices (such as network entities 105, UEs 115). The device 705 may include components for transmitting and receiving communication, which may include a processing system 720, an input/output (I/O) controller, such as an I/O controller 710, a transceiver 715, antenna(s) 725, a memory 730, and a processor 740. Components of the device 705 may be coupled (such as operatively, communicatively, functionally, electronically, electrically, in electronic communication) a bus 755.

The transceiver 715 may support bi-directional communication via antenna(s) 725, and may support transmission operations, reception operations, or both, as described herein. The transceiver 715 may implement functionality of a modem (such as a wireless modem) and may include one or more RF chains. An RF chain may include one or more filters, mixers, oscillators, amplifiers, analog-to-digital converters (ADCs), and other components that convert between an analog signal (such as for transmission or reception via an air interface) and a digital signal (such as for digital processing at the device 705). The transceiver 715 may modulate symbols and provide the modulated symbols to antenna(s) 725 for transmission, and demodulate symbols from signals received using antenna(s) 725.

The processor 740 may be a general-purpose processing component that supports various operations (such as applications) of the device 705. The memory 730 may be a general-purpose storage component that stores code executable by the processor 740. Such code may include instructions that, when executed by the processor 740, cause the device 705 to perform various functions (such as to support an application of the device 705). The I/O controller 710 may manage inputs and outputs for the device 705, may manage peripherals not integrated into the device 705, or may represent a physical connection (such as port) to an external peripheral. The processor 740 may interact with a modem, a keyboard, a mouse, a touchscreen, or other device (such as via I/O controller 710). In some implementations, a user may interact with the device 705 via the I/O controller 710 or via hardware components controlled by the I/O controller 710.

The processing system 720 may be an example of a processing system 140 or a processing system 620. For example, the processing system 720 may include processor circuitry 745 and memory circuitry 750 that stores code, and may be configured to cause the device 705 to perform operations that support LDPC techniques in wireless communications. Although the processing system 720 is illustrated as a separate component, which may involve a separate chip, chipset, or other module, in some implementations, one or more functions described with reference to the processing system 720 may be supported by or performed by a transceiver 715, antenna(s) 725, a processor 740, memory 730, or any combination thereof, such that a processing system 720 may include one or more of a transceiver 715, antenna(s) 725, a processor 740, memory 730, or any combination thereof.

By including or configuring the processing system 720 for operation in the device 705 as described herein, may support techniques for faster convergence for decoding LDPC codes, which may provide for efficient processing using less processing resources per decoding of CBs.

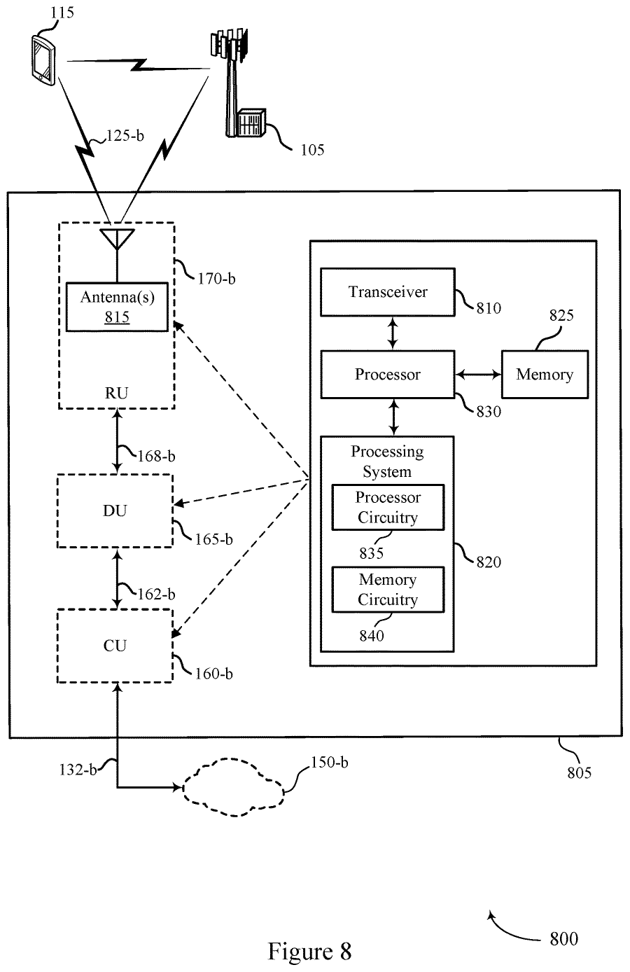

FIG. 8 shows an example of a system 800 including a device 805 that supports LDPC techniques in wireless communications. The device 805 may communicate (such as via one or more wired interfaces or one or more wireless interfaces) with other network devices or network equipment such as a core network 150-b, other network entities 105, UEs 115, or any combination thereof. The device 805 may include components for transmitting and receiving communication, which may include a processing system 820, a transceiver 810, antenna(s) 815, a memory 825, and a processor 830. Components of the device 805 may be coupled (such as operatively, communicatively, functionally, electronically, electrically, in electronic communication) via one or more interfaces.

The transceiver 810 may communicate bi-directionally with another transceiver via wired or wireless links, and may support transmission operations, reception operations, or both, as described herein. The transceiver 810 may include a modem to modulate and demodulate signals, to provide the modulated signals for transmission (such as via antenna(s) 815, via a wired interface), and to demodulate received signals (such as received via antenna(s) 815, received via a wired interface). The transceiver 810 may be operable to support communication via one or more communication links (such as a communication link 125-b, a backhaul link 132-b, a midhaul link 162-b, fronthaul link 168-b).

The processor 830 may be a general-purpose processing component that supports various operations (such as applications) of the device 805. The memory 825 may be a general-purpose storage component that stores code executable by the processor 830. Such code may include instructions that, when executed by the processor 830, cause the device 805 to perform various functions (such as to support an application of the device 805).

For examples in which the device 805 is a network entity 105 in a disaggregated architecture, one or more components of the device 805 may be located at one or more of a CU 160-b, a DU 165-b, or an RU 170-b, one or more of which may include aspects of the processing system 820, the processor 830, the memory 825, or the transceiver 810. Functions of the device 805 may be performed at different components or an operation may be divided between different components (such as different functions being supported by aspects of the CU 160-b, the DU 165-b, or the RU 170-b, the transceiver 810, the processor 830, the memory 825, the processing system 820, or any combination thereof). For example, the processing system 820 may be a component of one or more of the CU 160-b, the DU 165-b, or the RU 170-b. In some examples, interfaces between components of device 805 (such as CU 160-b, DU 165-b, RU 170-b) may support communication at a protocol layer or between protocol layers of a protocol stack.

In some examples, the processing system 820 may manage aspects of communication with the core network 150-b (such as via a backhaul link 132). For example, the processing system 820 may manage the transfer of data communication for UEs 115 with a gateway of the core network 150-b. In some examples, the processing system 820 may manage communication with one or more other network entities 105 and may include a controller or scheduler for controlling communication with UEs 115 (such as in cooperation with the one or more other network entities 105). In some examples, the processing system 820 may support an interface (such as X2 interface, Xn interface) to provide communication between network entities 105.

The processing system 820 may be an example of a processing system 145 or a processing system 620. For example, the processing system 820 may include processor circuitry 835 and memory circuitry 840 that stores code, and the processing system 820 may be configured to cause the device 805 to perform operations that support LDPC techniques in wireless communications. Although the processing system 820 is illustrated as a separate component, which may involve a separate chip, chipset, or other module, in some implementations, one or more functions described with reference to the processing system 820 may be supported by or performed by a transceiver 810, antenna(s) 815, a processor 830, memory 825, or any combination thereof, such that a processing system 820 may include one or more of a transceiver 810, antenna(s) 815, a processor 830, memory 825, or any combination thereof. Further, processor circuitry 835 and memory circuitry 840 each may be implemented at the device 805 in accordance with an aggregated architecture, or the processor circuitry 835 and the memory circuitry 840 may be implemented at one or more of a CU 160-b, a DU 165-b, or an RU 170-b in accordance with a disaggregated architecture.

By including or configuring the processing system 820 for operation in the device 805 as described herein, may support techniques for faster convergence for decoding LDPC codes, which may provide for efficient processing using less processing resources per decoding of CBs.

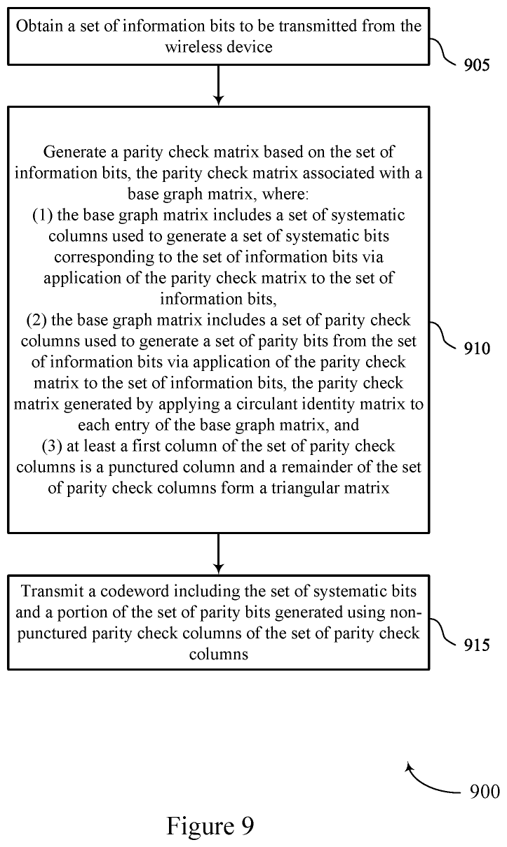

FIG. 9 shows an example of a method 900 that supports LDPC techniques in wireless communications. Operations of the method 900 may be performed by a UE 115 or a network entity 105 or respective components (such as using a processing system configured to cause the respective device to perform one or more of the operations), as described herein.

At 905, the method may include obtaining a set of information bits to be transmitted from the wireless device. In some examples, aspects of the operations of 905 may be performed by an information bit manager 625.

At 910, the method may include generating a parity check matrix based on the set of information bits, the parity check matrix associated with a base graph matrix, where the base graph matrix includes a set of systematic columns used to generate a set of systematic bits corresponding to the set of information bits via application of the parity check matrix to the set of information bits, where the base graph matrix includes a set of parity check columns used to generate a set of parity bits from the set of information bits via application of the parity check matrix to the set of information bits, the parity check matrix generated by applying a circulant identity matrix to each entry of the base graph matrix, where at least a first column of the set of parity check columns is a punctured column and a remainder of the set of parity check columns form a triangular matrix. In some examples, aspects of the operations of 910 may be performed by a parity matrix manager 630.

At 915, the method may include transmitting a codeword including the set of systematic bits and a portion of the set of parity bits generated using non-punctured parity check columns of the set of parity check columns. In some examples, aspects of the operations of 915 may be performed by a codeword transmission manager 635.

Implementation examples are described in the following numbered clauses:
Aspect 1: A method for wireless communications at a wireless device, comprising: obtaining a set of information bits to be transmitted from the wireless device; generating a parity check matrix based at least in part on the set of information bits, the parity check matrix associated with a base graph matrix, wherein: the base graph matrix comprises a set of systematic columns used to generate a set of systematic bits corresponding to the set of information bits via application of the parity check matrix to the set of information bits, the base graph matrix comprises a set of parity check columns used to generate a set of parity bits from the set of information bits via application of the parity check matrix to the set of information bits, the parity check matrix generated by applying a circulant identity matrix to each entry of the base graph matrix, and at least a first column of the set of parity check columns is a punctured column and a remainder of the set of parity check columns form a triangular matrix; and transmitting a codeword comprising the set of systematic bits and a portion of the set of parity bits generated using non-punctured parity check columns of the set of parity check columns.
Aspect 2: The method of aspect 1, wherein the first column comprises at least one value greater than one.
Aspect 3: The method of aspect 2, wherein the circulant identity matrix is a Z by Z identity matrix that is shifted in accordance with a cyclic shift value of a corresponding element of the base graph matrix, and where available values for Z are selected based on a quantity of edges of the base graph matrix, where an edge of the base graph matrix corresponds to an element of the base graph matrix that has an adjacent non-zero element of the base graph matrix.
Aspect 4: The method of aspect 3, wherein respective values of respective elements of the base graph matrix corresponds to a quantity of cyclic shift values to apply to the respective elements.
Aspect 5: The method of any of aspects 1 through 4, further comprising performing one or more row permutations or column permutations on an original base graph matrix to generate the base graph matrix that forms the triangular matrix.
Aspect 6: The method of any of aspects 1 through 5, wherein a second column of the remainder of the set of parity check columns has a connection to a single edge of the first column, and the second column has a higher transmission priority than a third column of the remainder of the set of parity check columns without a connection to the single edge of the first column.
Aspect 7: The method of any of aspects 1 through 6, wherein the base graph matrix comprises multiple indexed rows, a parity check node of a second column of the remainder of the set of parity check columns has a connection to a single edge of the first column, the parity check node is positioned in a lowest indexed row of the multiple indexed rows, and lower indexed rows of the multiple indexed rows have higher transmission priority than higher indexed rows of the multiple indexed rows.
Aspect 8: The method of any of aspects 1 through 7, wherein the remainder of the set of parity check columns comprise three columns.
Aspect 9: The method of any of aspects 1 through 8, wherein at least a portion of the set of systematic bits are mapped to an MSB of a modulation constellation, and at least a portion of the set of parity bits are mapped to an LSB of the modulation constellation.
Aspect 10: The method of any of aspects 1 through 9, wherein a dimension of the circulant identity matrix is Z×Z, and a total size of the parity check matrix is a size of the base graph matrix multiplied by Z.
Aspect 11: The method of any of aspects 1 through 10, wherein a coding rate used to encode the set of information bits into the codeword is between 0.95 and 1.
Aspect 12: A wireless device for wireless communications, comprising a processing system that includes processor circuitry and memory circuitry that stores code, the processing system configured to cause the wireless device to perform a method of any of aspects 1 through 11.
Aspect 13: A wireless device for wireless communications, comprising at least one means for performing a method of any of aspects 1 through 11.
Aspect 14: A non-transitory computer-readable medium storing code for wireless communications, the code comprising instructions executable by one or more processors to perform a method of any of aspects 1 through 11.

It should be noted that methods described herein describe possible implementations. Other implementations in accordance with the described techniques are possible, including implementations in which operations are rearranged or otherwise modified relative to the described methods. Further, aspects from two or more of the described methods may be combined.

Although aspects of 5G or 6G systems may be described for purposes of example and corresponding terminology may be used in the description, the techniques described herein are applicable beyond 5G, or 6G networks. For example, the described techniques may be applicable to other communication systems such as Institute of Electrical and Electronics Engineers (IEEE) 802.11 (Wi-Fi), IEEE 802.20, Flash-OFDM, or other systems and radio technologies not explicitly mentioned herein.

As used herein, a processing system (such as a processing system 140, a processing system 145) includes processor (or “processing”) circuitry in the form of one or multiple processors, microprocessors, processing units (such as central processing units (CPUs), graphics processing units (GPUs), neural processing units (NPUs) (also referred to as neural network processors or deep learning processors (DLPs)), or digital signal processors (DSPs)), processing blocks, application-specific integrated circuits (ASICs), programmable logic devices (PLDs), or other discrete gate or transistor logic or circuitry (any one or more of which may be generally referred to herein individually as a “processor” or collectively as “the processor” or “the processor circuitry”). Such processors may be individually or collectively configurable or configured to perform functions or operations described herein. A group of processors collectively configurable or configured to cause a device to perform a set of functions may include a first processor configured to cause the device to perform a first function of the set and a second processor configured to cause the device to perform a second function of the set. In some other examples, each of a group of processors may be configured to cause a device to perform a same set of functions.

As used herein, a processing system (such as a processing system 140, a processing system 145) also includes memory circuitry in the form of one or multiple memory devices, memory blocks, memory elements, or other discrete gate or transistor logic or circuitry, each of which may include or implement tangible storage media such as random-access memory (RAM) or read-only memory (ROM), or combinations thereof (any one or more of which may be generally referred to herein individually as a “memory” or collectively as “the memory” or “the memory circuitry”). One or more of the memories may be coupled (such as operatively, communicatively, electronically, electrically) with one or more processors of the processor circuitry and may individually or collectively store processor-executable code or instructions (such as software) that, when executed by one or more of the processors, may cause a device (such as configure the device, using one or more of the processors) to perform functions or operations described herein. Additionally, or alternatively, in some examples, one or more of the processors may be configured to cause a device to perform functions or operations described herein without requiring configuration by software. As used herein, “software” shall be construed to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise.

As used herein, a processing system (such as a processing system 140, a processing system 145) may include or be coupled with one or more modems (such as a cellular modem, a 5G-compliant modem, a 6G-compliant modem). In some examples, one or more processors of a processing system may include or implement one or more of the modems. A processing system also may include or be coupled with multiple radios (collectively “the radio”), multiple RF chains, or multiple transceivers, each of which may in turn be coupled with one or more of multiple antennas. In some examples, one or more processors of a processing system may include or implement one or more of the radios, RF chains, or transceivers. An RF chain may include one or more filters, mixers, oscillators, amplifiers, analog-to-digital converters (ADCs), or other devices that convert between an analog signal (such as for transmission or reception via an air interface) and a digital signal (such as for processing by processor circuitry).

As described herein, being “configured to,” being “configurable to,” and being “operable to” may be used interchangeably and may be associated with a capability, when executing code (such as processor-executable code, instructions) stored in memory circuitry (such as a non-transitory computer-readable medium, of the memory circuitry, storing code for wireless communication that is executable by a processing system) or otherwise, to perform one or more of the functions described herein.

As used herein, the term “determine” or “determining” can encompass one or more of a variety of actions. For example, “determining” can include one or more of calculating, computing, processing, deriving, detecting, estimating, looking up, inferring, ascertaining, measuring, resolving, selecting, obtaining, identifying, interpreting, demodulating, decoding, reading, establishing, forming, or generating, among other examples. In some such examples, determining can involve a processing system performing some type of calculating, computing, deriving, estimating, inferring, ascertaining, resolving, predicting, or other processing to obtain one or more numerical values, sets, elements, or other information or results. In some such examples, determining can involve a processing system identifying, looking up, investigating or otherwise obtaining some type of value, set, element, or other information or result from a table, data structure, database, or an implementation of memory, such as from a larger set of values, sets, or elements or other information or results. In some such examples, determining can involve a processing system identifying, interpreting, demodulating, decoding, detecting, reading, or otherwise obtaining some type of value, set, element, or other information or result signaled in, for example, a received wireless signal. In some such examples, determining can involve a processing system performing a measurement, such as on a received signal.

As used herein, a phrase referring to “at least one of” or “one or more of” a list of items refers to any combination of those items, including single members. For example, “at least one of: a, b, or c” is intended to cover: a, b, c, a-b, a-c, b-c, and a-b-c. Additionally, as used herein, a phrase referring to “a” or “an” element refers to one or more of such elements acting individually or collectively to perform the recited function(s). Thus, the terms “a,” “at least one,” “one or more,” and “at least one of one or more” may be interchangeable. For instance, for a claim that refers to “a” component performing one or more functions, each of the individual functions may be performed by a single component or by any combination of multiple components, and subsequent reference to a component introduced with the article “a” using the term “the” may refer to any or all of the single or multiple components. Thus, a component introduced with the article “a” may be understood to mean “one or more” components, and referring to “the” component subsequently in the claims may be understood to be equivalent to referring to “at least one of the one or more” components. Additionally, as used herein, a “set” can refer to one or more items, and a “subset” can refer to a whole set or less than the whole set, but not an empty set. Additionally, as used herein, the term “or” is intended to be interpreted in the inclusive sense, such as when referring to a series, and may be used interchangeably with the term “and/or,” unless otherwise explicitly indicated (for example, if used in conjunction with “either” or “only one of”). For example, “a or b” may include a only, b only, or a combination of a and b.

The disclosure is provided to enable a person having ordinary skill in the art to implement the described techniques. Modifications to the disclosure will be apparent to a person having ordinary skill in the art, and the techniques disclosed herein may be applied with other variations without departing from the scope of the disclosure. Thus, the disclosure is not limited to the examples and designs described herein but is to be accorded the broadest scope consistent with the principles and novel features disclosed herein.

What is claimed is:

1. A wireless device, comprising:
a processing system that includes processor circuitry and memory circuitry that stores code, the processing system configured to cause the wireless device to:
obtain a set of information bits to be transmitted from the wireless device;
generate a parity check matrix based at least in part on the set of information bits, the parity check matrix associated with a base graph matrix, wherein:
the base graph matrix comprises a set of systematic columns used to generate a set of systematic bits corresponding to the set of information bits via application of the parity check matrix to the set of information bits,
the base graph matrix comprises a set of parity check columns used to generate a set of parity bits from the set of information bits via application of the parity check matrix to the set of information bits, the parity check matrix generated by applying a circulant identity matrix to each entry of the base graph matrix, and
at least a first column of the set of parity check columns is a punctured column and a remainder of the set of parity check columns form a triangular matrix; and
transmit a codeword comprising the set of systematic bits and a portion of the set of parity bits generated using non-punctured parity check columns of the set of parity check columns.

2. The wireless device of claim 1, wherein:
the first column comprises at least one value greater than one.

3. The wireless device of claim 2, wherein the circulant identity matrix is a Z by Z identity matrix that is shifted in accordance with a cyclic shift value of a corresponding element of the base graph matrix, and where available cyclic shift values for Z are selected based on a quantity of edges of the base graph matrix, where an edge of the base graph matrix corresponds to an element of the base graph matrix that has an adjacent non-zero element of the base graph matrix.

4. The wireless device of claim 3, wherein respective values of respective elements of the base graph matrix corresponds to a quantity of cyclic shift values to apply to the respective elements.

5. The wireless device of claim 1, wherein the processing system configured to cause the wireless device to:
perform one or more row permutations or column permutations on an original base graph matrix to generate the base graph matrix that forms the triangular matrix.

6. The wireless device of claim 1, wherein:
a second column of the remainder of the set of parity check columns has a connection to a single edge of the first column, and
the second column has a higher transmission priority than a third column of the remainder of the set of parity check columns without a connection to the single edge of the first column.

7. The wireless device of claim 1, wherein:
the base graph matrix comprises multiple indexed rows,
a parity check node of a second column of the remainder of the set of parity check columns has a connection to a single edge of the first column,
the parity check node is positioned in a lowest indexed row of the multiple indexed rows, and
lower indexed rows of the multiple indexed rows have higher transmission priority than higher indexed rows of the multiple indexed rows.

8. The wireless device of claim 1, wherein:
the remainder of the set of parity check columns comprise three columns.

9. The wireless device of claim 1, wherein:
at least a portion of the set of systematic bits are mapped to a most significant bit of a modulation constellation, and
at least a portion of the set of parity bits are mapped to a least significant bit of the modulation constellation.

10. The wireless device of claim 1, wherein a dimension of the circulant identity matrix is Z×Z, and a total size of the parity check matrix is a size of the base graph matrix multiplied by Z.

11. The wireless device of claim 1, wherein a coding rate used to encode the set of information bits into the codeword is between 0.95 and 1.

12. A method for wireless communications at a wireless device, comprising:
obtaining a set of information bits to be transmitted from the wireless device;
generating a parity check matrix based at least in part on the set of information bits, the parity check matrix associated with a base graph matrix, wherein:
the base graph matrix comprises a set of systematic columns used to generate a set of systematic bits corresponding to the set of information bits via application of the parity check matrix to the set of information bits,
the base graph matrix comprises a set of parity check columns used to generate a set of parity bits from the set of information bits via application of the parity check matrix to the set of information bits, the parity check matrix generated by applying a circulant identity matrix to each entry of the base graph matrix, and
at least a first column of the set of parity check columns is a punctured column and a remainder of the set of parity check columns form a triangular matrix; and
transmitting a codeword comprising the set of systematic bits and a portion of the set of parity bits generated using non-punctured parity check columns of the set of parity check columns.

13. The method of claim 12, wherein the first column comprises at least one value greater than one.

14. The method of claim 13, wherein the circulant identity matrix is a Z by Z identity matrix that is shifted in accordance with a cyclic shift value of a corresponding element of the base graph matrix, and where available values for Z are selected based on a quantity of edges of the base graph matrix, where an edge of the base graph matrix corresponds to an element of the base graph matrix that has an adjacent non-zero element of the base graph matrix.

15. The method of claim 12, further comprising:
performing one or more row permutations or column permutations on an original base graph matrix to generate the base graph matrix that forms the triangular matrix.

16. The method of claim 12, wherein:
a second column of the remainder of the set of parity check columns has a connection to a single edge of the first column, and
the second column has a higher transmission priority than a third column of the remainder of the set of parity check columns without a connection to the single edge of the first column.

17. The method of claim 12, wherein:
the base graph matrix comprises multiple indexed rows,
a parity check node of a second column of the remainder of the set of parity check columns has a connection to a single edge of the first column,
the parity check node is positioned in a lowest indexed row of the multiple indexed rows, and
lower indexed rows of the multiple indexed rows have higher transmission priority than higher indexed rows of the multiple indexed rows.

18. The method of claim 12, wherein the remainder of the set of parity check columns comprise three columns.

19. The method of claim 12, wherein:
at least a portion of the set of systematic bits are mapped to a most significant bit of a modulation constellation, and
at least a portion of the set of parity bits are mapped to a least significant bit of the modulation constellation.

20. A non-transitory computer-readable medium storing code for wireless communications at a wireless device, the code comprising instructions executable by one or more processors to:
obtain a set of information bits to be transmitted from the wireless device;
generate a parity check matrix based at least in part on the set of information bits, the parity check matrix associated with a base graph matrix, wherein:
the base graph matrix comprises a set of systematic columns used to generate a set of systematic bits corresponding to the set of information bits via application of the parity check matrix to the set of information bits,
the base graph matrix comprises a set of parity check columns used to generate a set of parity bits from the set of information bits via application of the parity check matrix to the set of information bits, the parity check matrix generated by applying a circulant identity matrix to each entry of the base graph matrix, and
at least a first column of the set of parity check columns is a punctured column and a remainder of the set of parity check columns form a triangular matrix; and
transmit a codeword comprising the set of systematic bits and a portion of the set of parity bits generated using non-punctured parity check columns of the set of parity check columns.
